(19) United States
(12) Patent Application Publication
(10) Pub. No.: US 2021/0407839 A1
(43) Pub. Date: Dec. 30, 2021

(54) SUBSTRATE PROCESSING APPARATUS AND SUBSTRATE PROCESSING METHOD

(71) Applicant: Tokyo Electron Limited, Tokyo (JP)

(72) Inventor: Tatsuhiko Tsujihashi, Koshi City (JP)

(21) Appl. No.: 17/359,897

(22) Filed: Jun. 28, 2021

(30) Foreign Application Priority Data
Jun. 30, 2020 (JP) 2020-112416

(51) Int. Cl. H01L 21/68; H01L 21/67

(52) U.S. Cl. CPC H01L 21/681; H01L 21/67253; H01L 21/67155

(57) ABSTRACT

A substrate processing apparatus includes a processing unit, a transit unit, a processing unit transfer device, an inspector and an inspector transfer device. The processing unit is configured to process a peripheral portion of a substrate. The substrate is transferred into/from the transit unit. The processing unit transfer device is configured to perform a carry-in/carry-out of the substrate between the transit unit and the processing unit. The inspector is configured to inspect a processed state of the peripheral portion of the substrate. The inspector transfer device is configured to take out the substrate from the inspector and carry the taken substrate into the transit unit.

### CROSS-REFERENCE TO RELATED APPLICATION

This application claims the benefit of Japanese Patent Application No. 2020-112416 filed on Jun. 30, 2020, the entire disclosure of which is incorporated herein by reference.

### TECHNICAL FIELD

The various aspects and embodiments described herein pertain generally to a substrate processing apparatus and a substrate processing method.

### BACKGROUND

Conventionally, there is known a substrate processing apparatus equipped with a processing unit configured to process a peripheral portion of a substrate such as a silicon wafer or a compound semiconductor wafer.

This kind of substrate processing apparatus may be equipped with an inspector configured to inspect the peripheral portion of the substrate to investigate whether the processing of the peripheral portion of the substrate is properly performed.

Patent Document 1 discloses a substrate processing apparatus having the inspector in a delivery station which is located between a carry-in/out station in which a substrate is carried into or out of a cassette and a processing station in which a periphery removing processing is performed.
Patent Document 1: Japanese Patent Laid-open Publication No. 2019-062011

### SUMMARY

In an exemplary embodiment, a substrate processing apparatus includes a processing unit, a transit unit, a processing unit transfer device, an inspector and an inspector transfer device. The processing unit is configured to process a peripheral portion of a substrate. The substrate is transferred into/from the transit unit. The processing unit transfer device is configured to perform a carry-in/carry-out of the substrate between the transit unit and the processing unit. The inspector is configured to inspect a processed state of the peripheral portion of the substrate. The inspector transfer device is configured to take out the substrate from the inspector and carry the taken substrate into the transit unit.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a top view illustrating a layout of a substrate processing system according to a first exemplary embodiment;

FIG. 2 is a side view illustrating the layout of the substrate processing system according to the first exemplary embodiment;

FIG. 3 is a side view illustrating the layout of the substrate processing system according to the first exemplary embodiment;

FIG. 4 is a rear view illustrating the layout of the substrate processing system according to the first exemplary embodiment;

FIG. 5 is a schematic diagram illustrating a periphery processing unit;

FIG. 6 is a schematic side view illustrating a first transit unit and an inspector;

FIG. 7 is a schematic top view illustrating the inspector according to the first exemplary embodiment;

FIG. 8 is a schematic side view illustrating the inspector according to the first exemplary embodiment;

FIG. 9 is a schematic perspective diagram illustrating a first imaging sub-unit and a second imaging sub-unit;

FIG. 10 is a schematic perspective diagram illustrating the first imaging sub-unit and the second imaging sub-unit;

FIG. 11 is a schematic side view illustrating the first imaging sub-unit;

FIG. 12 is a flowchart illustrating a sequence of processings performed by the substrate processing system according to the first exemplary embodiment;

FIG. 13 is a diagram illustrating a transfer flow of a wafer in the substrate processing system according to the first exemplary embodiment;

FIG. 14 is a diagram illustrating the transfer flow of the wafer in the substrate processing system according to the first exemplary embodiment;

FIG. 15 is a diagram illustrating the transfer flow of the wafer in the substrate processing system according to the first exemplary embodiment;

FIG. 16 is a top view illustrating a layout of a substrate processing system according to a second exemplary embodiment;

FIG. 17 is a side view illustrating the layout of the substrate processing system according to the second exemplary embodiment;

FIG. 18 is a rear view illustrating a layout of a delivery station of the substrate processing system according to the second exemplary embodiment;

FIG. 19 is a schematic top view illustrating an inspector according to the second exemplary embodiment;

FIG. 20 is a schematic top view illustrating a first transit unit according to the second exemplary embodiment;

FIG. 21 is a schematic top view illustrating a second transit unit according to the second exemplary embodiment;

FIG. 22 is a diagram illustrating a transfer flow of a wafer in the substrate processing system according to the second exemplary embodiment;

FIG. 23 is a diagram illustrating the transfer flow of the wafer in the substrate processing system according to the second exemplary embodiment;

FIG. 24 is a diagram illustrating the transfer flow of the wafer in the substrate processing system according to the second exemplary embodiment;

FIG. 25 is a top view illustrating a layout of a substrate processing system according to a third exemplary embodiment;

FIG. 26 is a side view illustrating the layout of the substrate processing system according to the third exemplary embodiment;

FIG. 27 is a side view illustrating the layout of the substrate processing system according to the third exemplary embodiment;

FIG. 28 is a diagram illustrating a transfer flow of a wafer in a substrate processing system according to the third exemplary embodiment;

FIG. 29 is a diagram illustrating the transfer flow of the wafer in the substrate processing system according to the third exemplary embodiment;

FIG. 30 is a diagram illustrating a transfer flow of a wafer in a substrate processing system according to a first modification example;

FIG. 31 is a diagram illustrating the transfer flow of the wafer in the substrate processing system according to the first exemplary embodiment;

FIG. 32 is a cross sectional top view illustrating an entire surface inspector according to the first modification example;

FIG. 33 is a cross sectional side view illustrating the entire surface inspector according to the first modification example;

FIG. 34 is a top view illustrating a layout of a substrate processing system according to a second modification example; and

FIG. 35 is a schematic diagram illustrating a bottom surface processing unit according to the second modification example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, embodiments for a substrate processing apparatus and a substrate processing method according to the present disclosure (hereinafter, referred to as “exemplary embodiments”) will be described in detail with reference to the accompanying drawings. Here, it should be noted that the present disclosure is not limited by the exemplary embodiments. Further, unless processing contents are contradictory, the various exemplary embodiments can be appropriately combined. Furthermore, in the various exemplary embodiments to be described below, same parts will be assigned same reference numerals, and redundant description will be omitted.

Further, in the following exemplary embodiments, expressions such as “constant,” “perpendicular,” “vertical” and “parallel” may be used. These expressions, however, do not imply strictly “constant”, “perpendicular,” “vertical” and “parallel”. That is, these expressions allow some tolerable errors in, for example, manufacturing accuracy, installation accuracy, or the like.

In the various drawings that are referred to in the following description, the X-axis direction, Y-axis direction and Z-axis direction which are orthogonal to each other are defined, and an orthogonal coordinate system in which the positive Z-axis direction is regarded as a vertically upward direction may be used in order to ease understanding of the description. Further, a rotational direction around a vertical axis may be referred to as “θ direction.”

### First Exemplary Embodiment

<Configuration of Substrate Processing System>

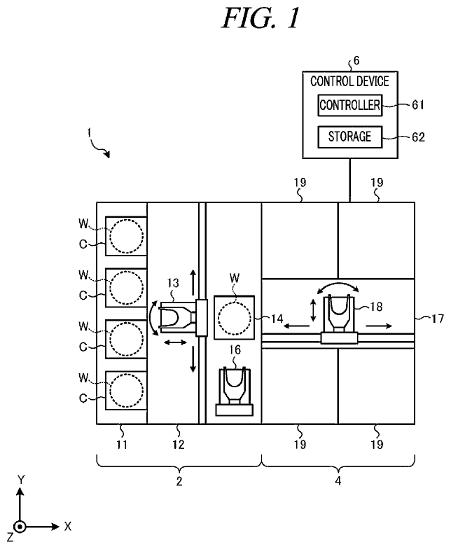

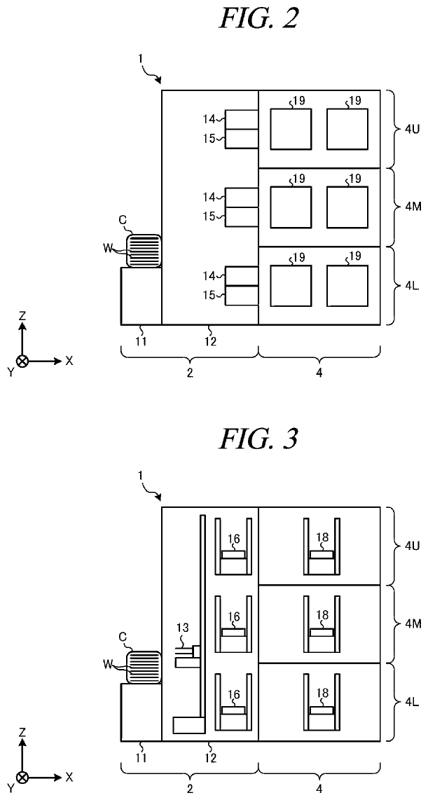

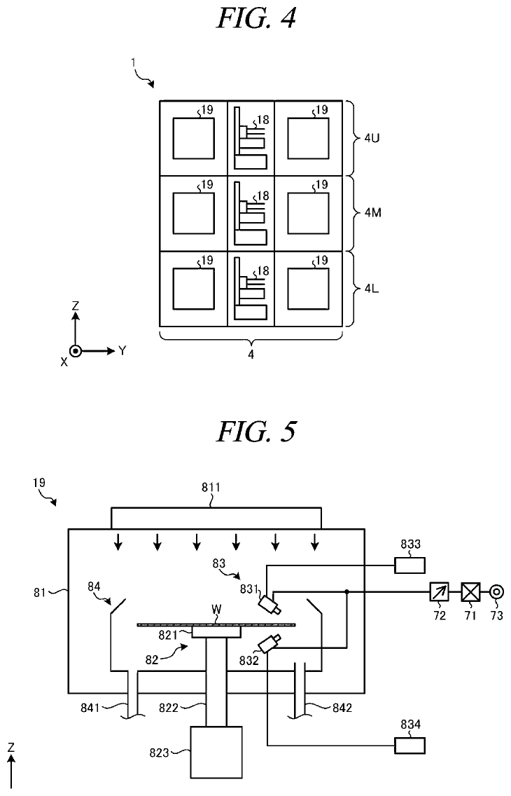

First, a configuration of a substrate processing system according to a first exemplary embodiment will be explained with reference to FIG. 1 to FIG. 4. FIG. 1 is a top view illustrating a layout of the substrate processing system according to the first exemplary embodiment. FIG. 2 and FIG. 3 are side views illustrating the layout of the substrate processing system according to the first exemplary embodiment. FIG. 2 mainly illustrates a layout of first transit units 14, inspectors 15 and periphery processing units 19 while omitting illustration of various kinds of transfer devices. FIG. 3 mainly illustrates a layout of the various kinds of transfer devices. FIG. 4 is a rear view illustrating the layout of the substrate processing system according to the first exemplary embodiment.

As depicted in FIG. 1, the substrate processing system 1 according to the first exemplary embodiment includes a carry-in/out station 2 and a processing station 4.

In the carry-in/out station 2, a substrate such as a semiconductor wafer (hereinafter, referred to as “wafer W”) is taken out of a cassette C and transferred into the processing station 4. In the processing station 4, a processing of the wafer W is performed. To elaborate, in the processing station 4, a periphery processing of processing a peripheral portion of the wafer W is performed.

Then, the wafer W is transferred from the processing station 4 back into the carry-in/out station 2 and accommodated in the cassette C. At this time, in the carry-in/out station 2, an inspection processing of inspecting the peripheral portion of the wafer W is performed before the wafer W is accommodated in the cassette C in order to investigate whether a film of the peripheral portion of the wafer W is properly removed.

(Carry-in/Out Station)

The carry-in/out station 2 includes a cassette placing section 11 and a transfer section 12. A plurality of cassettes C each of which accommodates therein a multiple number of wafers W is disposed in the cassette placing section 11.

The transfer section 12 is disposed between the cassette placing section 11 and the processing station 4. As shown in FIG. 1 to FIG. 3, the transfer section 12 is equipped with a first transfer device 13 (an example of a cassette transfer device), a plurality of first transit units 14, a plurality of inspectors 15, and a plurality of second transfer devices 16 (inspector transfer devices).

The first transfer device 13 is configured to carry the wafer W between the cassette C and the first transit units 14. The first transfer device 13 is equipped with a multiple number of supports each of which is configured to support a single sheet of wafer W from below it. By way of example, the first transfer device 13 has more than two supports. The first transfer device 13 is movable in a horizontal direction and a vertical direction and pivotable around a vertical axis, and is capable of transferring a multiple number of wafers W at the same time between the cassette C and the first transit units 14. As shown in FIG. 3, the transfer section 12 is provided with the single first transfer device 13.

The wafers W to be carried into or from the cassettes C are placed in the plurality of first transit units 14. That is, the wafers W carried out from the cassette C and the wafers W to be carried into the cassette C are placed in the first transit units 14. Each first transit unit 14 is capable of accommodating therein a plurality of wafers W in multiple levels in the vertical direction.

Each of the plurality of inspectors 15 is configured to inspect a processed state of a peripheral portion of the wafer W. A specific configuration of the inspector 15 will be elaborated later.

The single first transit unit 14 and the single inspector 15 are stacked on top of each other in a height direction. In the substrate processing system 1, blocks each of which includes the single first transit unit 14 and the single inspector 15 are stacked in multiple levels in the height direction. To elaborate, the processing station 4 to be described later includes an upper processing block 4U, a middle processing block 4M and a lower processing block 4U stacked in multiple levels. The blocks each of which includes the single first transit unit 14 and the single inspector 15 are disposed at positions respectively corresponding to the upper processing block 4U, the middle processing block 4M and the lower processing block 4L in one-to-one correspondence.

In the present exemplary embodiment, the inspector 15 is disposed under the first transit unit 14. However, the first transit unit 14 may be disposed under the inspector 15.

The plurality of second transfer devices 16 are arranged in multiple levels to correspond to the plurality of blocks each of which is composed of the first transit unit 14 and the inspector 15, respectively. Each second transfer device 16 takes out the wafer W from the inspector 15 of the corresponding block and carries the taken wafer W into the first transit unit 14 of this corresponding block.

The second transfer devices 16 are disposed beside the first transit units 14. To elaborate, the second transfer devices 16 are provided adjacent to the first transit units 14 in a horizontal direction (Y-axis direction) perpendicular to an arrangement direction (X-axis direction) of the carry-in/out station 2 and the processing station 4. Further, the first transfer device 13 and third transfer devices 18 to be described later are adjacent to the first transit units 14 in the X-axis direction.

Each second transfer device 16 is equipped with a plurality of supports each of which supports a single sheet of wafer W from below it. For example, the second transfer device 16 has two supports, and is capable of performing a carry-in/carry-out of two wafers W with the supports individually. The second transfer device 16 is movable in the vertical direction, and is capable of transferring the wafer W between the first transit unit 14 and the inspector 15 which are vertically stacked on top of each other.

(Processing Station)

The processing station 4 is equipped with, as illustrated in FIG. 2 to FIG. 4, the upper processing block 4U, the middle processing block 4M and the lower processing block 4L. The upper processing block 4U, the middle processing block 4M and the lower processing block 4L are spatially separated from each other by partition walls or shutters, and are arranged in the height direction.

The upper processing block 4U, the middle processing block 4M and the lower processing block 4L have the same configuration. To be specific, each of the processing blocks 4U, 4M and 4L includes, as depicted in FIG. 1, a transfer section 17 and a plurality of periphery processing units 19.

The transfer section 17 is provided adjacent to the transfer section 12 of the carry-in/out station 2. To elaborate, the transfer section 17 is provided adjacent to the first transit units 14 disposed in the transfer section 12. Further, the periphery processing units 19 are arranged at both sides (the positive Y-axis direction and the negative Y-axis direction) of the transfer section 17.

For example, in the shown example, two periphery processing units 19 are arranged at a positive Y-axis side of the transfer section 17 side by side along the X-axis direction. Further, two periphery processing units 19 are arranged at a negative Y-axis side of the transfer section 17 side by side along the X-axis direction. That is, the four periphery processing units 9 in total are disposed in each of the upper processing block 4U, the middle processing block 4M and the lower processing block 4L.

The transfer section 17 is equipped with the third transfer devices 18 (an example of processing unit transfer devices) configured to carry the wafers W between the first transit units 14 and the periphery processing units 19. Each third transfer device 18 is provided with a plurality of supports each of which supports a single sheet of wafer W from below it. By way of example, the third transfer device 18 is equipped with two supports, and is capable of performing a carry-in/carry-out of two wafers W with the supports individually.

The third transfer device 18 is movable in a horizontal direction and a vertical direction and pivotable around a vertical axis, and performs a carry-in/carry-out of the wafer W between the first transit unit 14 and the periphery processing unit 19 corresponding to the single processing block 4U (4M, 4L). Further, the third transfer device 18 according to the first exemplary embodiment also performs a processing of carrying the wafer W after being processed in the periphery processing unit 19 into the corresponding inspector 15.

The periphery processing unit 19 is configured to perform a periphery processing of processing a peripheral portion of the wafer W. To elaborate, the periphery processing unit 19 performs a periphery removing processing of removing a film from a bevel portion of the wafer W by etching. Here, the bevel portion refers to an end surface of the wafer W and an inclined portion formed around it. The inclined portion is formed at each of a top surface peripheral portion and a bottom surface peripheral portion.

Here, however, the periphery processing is not necessarily limited to the processing of removing the film. By way of example, the periphery processing unit 19 may perform a periphery cleaning processing of cleaning the bevel portion of the wafer W as the periphery processing.

Here, a configuration of the periphery processing unit 19 will be explained with reference to FIG. 5. FIG. 5 is a schematic diagram illustrating the periphery processing unit 19.

As depicted in FIG. 5, the periphery processing unit 19 includes a chamber 81, a substrate holding mechanism 82, a supply 83 and a recovery cup 84.

The chamber 81 accommodates therein the substrate holding mechanism 82, the supply 83 and the recovery cup 84. A FFU (Fan Filter Unit) 811 configured to create a downflow within the chamber 81 is provided at a ceiling of the chamber 81.

The substrate holding mechanism 82 is equipped with a holder 821 configured to hold the wafer W horizontally; a vertically extending supporting column 822 configured to support the holder 821; and a driver 823 configured to rotate the supporting column 822 around a vertical axis.

The holder 821 is connected to an air suction device (not shown) such as a vacuum pump, and holds the wafer W horizontally by attracting a bottom surface of the wafer W through the use of a negative pressure generated by air suction of the air suction device. By way of non-limiting example, a porous chuck, an electrostatic chuck, or the like may be used as the holder 821.

The holder 821 has an attraction region having a diameter smaller than a diameter of the wafer W. Accordingly, a chemical liquid discharged from a lower nozzle 832 of the supply 83 to be described later can be supplied to the bottom surface peripheral portion of the wafer W.

The supply 83 is equipped with an upper nozzle 831 and the lower nozzle 832. The upper nozzle 831 is disposed above the wafer W held by the substrate holding mechanism 82, and the lower nozzle 832 is disposed under the wafer W.

The upper nozzle 831 and the lower nozzle 832 are connected with a chemical liquid source 73 via a valve 71 and a flow rate controller 72. The upper nozzle 831 discharges the chemical liquid such as hydrofluoric acid (HF) or nitric acid (HNO₃) from the chemical liquid source 73 onto the top surface peripheral portion of the wafer W held by the substrate holding mechanism 82. The lower nozzle 832 discharges the chemical liquid from the chemical liquid source 73 onto the bottom surface peripheral portion of the wafer W held by the substrate holding mechanism 82.

Further, the supply 83 is further equipped with a first moving mechanism 833 configured to move the upper nozzle 831 and a second moving mechanism 834 configured to move the lower nozzle 832. By moving the upper nozzle 831 and the lower nozzle 832 by using the first moving mechanism 833 and the second moving mechanism 834, respectively, a supply position of the chemical liquid onto the wafer W can be varied.

The recovery cup 84 is disposed to surround the substrate holding mechanism 82. A drain port 841 is formed at a bottom portion of the recovery cup 84 to drain the chemical liquid supplied from the supply 83 to an outside of the chamber 81. Further, an exhaust port 842 is formed at the bottom portion of the recovery cup 84 to exhaust an atmosphere within the chamber 81.

The periphery processing unit 19 having the above-described configuration attracts and holds the bottom surface of the wafer W with the holder 821 and then rotates the wafer W by using the driver 823. Further, the periphery processing unit 19 discharges the chemical liquid from the upper nozzle 831 toward the top surface peripheral portion of the wafer W being rotated, and discharges the chemical liquid from the lower nozzle 832 toward the bottom surface peripheral portion of the wafer W being rotated. As a result, a film attached to the bevel portion of the wafer W is removed. At this time, a contaminant such as a particle attached to the bevel portion of the wafer W is also removed along with the film.

Further, the periphery processing unit 19 may perform a rinsing processing of washing away the chemical liquid remaining on the bevel portion of the wafer W by discharging a rinse liquid such as pure water from the upper nozzle 831 and the lower nozzle 832 after performing the above-stated periphery removing processing. Further, the periphery processing unit 19 may perform a drying processing of drying the wafer W by rotating the wafer W after the rinsing processing.

As depicted in FIG. 1, the substrate processing system 1 is equipped with a control device 6. The control device 6 is, for example, a computer, and includes a controller 61 and a storage 62. The storage 62 stores a program that controls various processings performed in the substrate processing system 1. The controller 61 is, for example, a CPU (Central Processing Unit), and controls an operation of the substrate processing system 1 by reading and executing the program stored in the storage 62.

Further, the program may be recorded in a computer-readable recording medium, and installed from the recording medium to the storage 62 of the control device 6. The computer-readable recording medium may be, for example, a hard disc (HD), a flexible disc (FD), a compact disc (CD), a magnet optical disc (MO), or a memory card. Furthermore, the controller 61 may be implemented by hardware only without using the program.

In the periphery removing processing, a removing width (a width along a diametrical direction of the wafer W with an edge of the wafer W being one end; hereinafter, referred to as “cut width”) of the film is set. If, however, the positions of the upper nozzle 831 and the lower nozzle 832 are not appropriate, an actual cut width may be deviated from the set cut width. Further, in case that a center of the wafer W is deviated from a rotation center of the substrate holding mechanism 82, the cut width may become non-uniform in a circumferential direction of the wafer W. For the reason, there may be performed an operation of imaging, with a camera, the wafer W after being subjected to the periphery removing processing and investigating whether the periphery removing processing has been performed appropriately based on the obtained image.

In the substrate processing system 1 according to the first exemplary embodiment, the inspector 15 configured to inspect the bevel portion of the wafer W after being subjected to the periphery removing processing is provided at an outside of the plurality of periphery processing units 19 and provided to correspond to these periphery processing units 19.

<Configuration of Inspector>

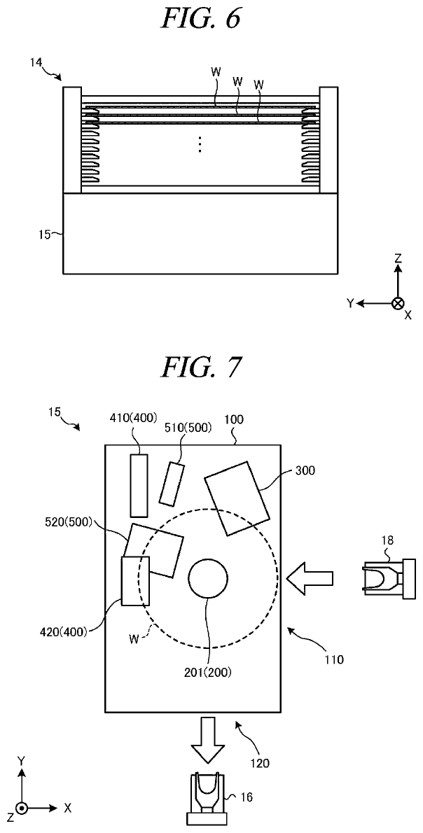

Below, a configuration of the inspector 15 according to the first exemplary embodiment will be described in detail with reference to FIG. 6 to FIG. 11.

FIG. 6 is a schematic side view illustrating the first transit unit 14 and the inspector 15. As shown in FIG. 6, the inspector 15 is provided under and adjacent to the first transit unit 14.

As stated above, by stacking the first transit unit 14 and the inspector 15 on top of each other in the height direction, an increase of a footprint of the substrate processing system 1 can be suppressed. Further, even if the dust or the like falls from the inspector 15, the falling dust can be suppressed from adhering to the wafer W placed in the first transit unit 14 as the inspector 15 is disposed under the first transit unit 14.

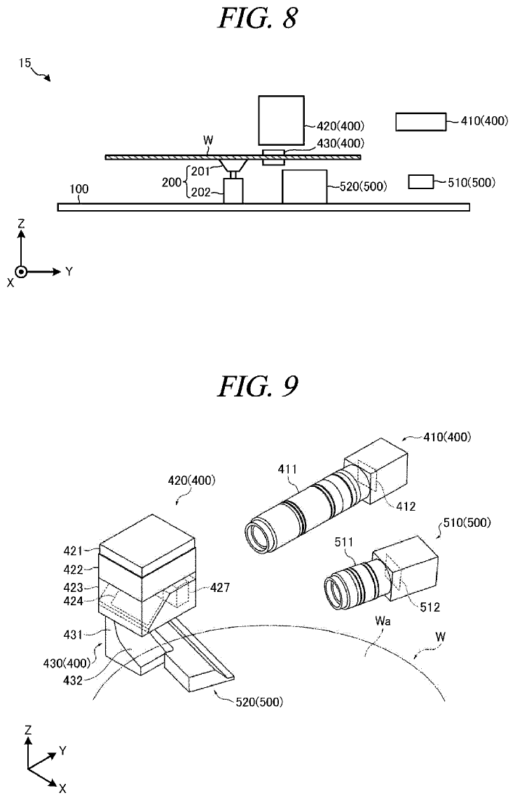

FIG. 7 is a schematic top view of the inspector 15 according to the first exemplary embodiment, and FIG. 8 is a schematic side view illustrating the inspector 15 according to the first exemplary embodiment. In FIG. 8, illustration of a notch detection sub-unit 300 is omitted.

As shown in FIG. 7, the inspector 15 includes a base plate 100, a rotating/holding sub-unit 200 (an example of a rotating/holding unit), the notch detection sub-unit 300 (an example of a detector), a first imaging sub-unit 400, and a second imaging sub-unit 500.

In the substrate processing system 1 according to the first exemplary embodiment, among the first transfer device 13, the second transfer device 16 and the third transfer device 18, the second transfer device 16 and the third transfer device 18 access the inspector 15.

To elaborate, the inspector 15 has a carry-in portion 110 and a carry-out portion 120 which are opened to different directions. The carry-in portion 110 is opened toward the transfer section 17, whereas the carry-out portion 120 is opened toward the second transfer device 16. The third transfer device 18 carries the wafer W into the inspector 15 through the carry-in portion 110, and the second transfer device 16 carries out the wafer W from the inspector 15 through the carry-out portion 120.

The base plate 100 is of, for example, a plate-shaped member, and the sub-units 200 to 500 are disposed on the base plate 100.

The rotating/holding sub-unit 200 is equipped with a holding table 201 and an actuator 202. The holding table 201 is, for example, an attraction chuck configured to hold the wafer W horizontally by attraction or the like. The holding table 201 has an attraction region having a diameter smaller than that of the wafer W. The actuator 202 is, for example, an electric motor and is configured to rotate the holding table 201.

The notch detection sub-unit 300 is configured to detect a position of a notch formed at the wafer W. By way of example, the notch detection sub-unit 300 is equipped with a non-illustrated horizontal structure. A light emitting element is provided at a bottom surface of the horizontal structure, and a light receiving element is provided at a top surface thereof. In the state that the wafer W is placed on the rotating/holding sub-unit 200, radiation light from the light emitting element is blocked by the peripheral portion of the wafer W, so the radiation light is not received by the light receiving element. If, however, the notch formed at the peripheral portion of the wafer W comes into a position where it faces the light emitting element as the wafer W is rotated by the rotating/holding sub-unit 200, the radiation light passes through the notch to be received by the light receiving element. Accordingly, the notch detection sub-unit 300 is capable of detecting the position of the notch formed at the wafer W.

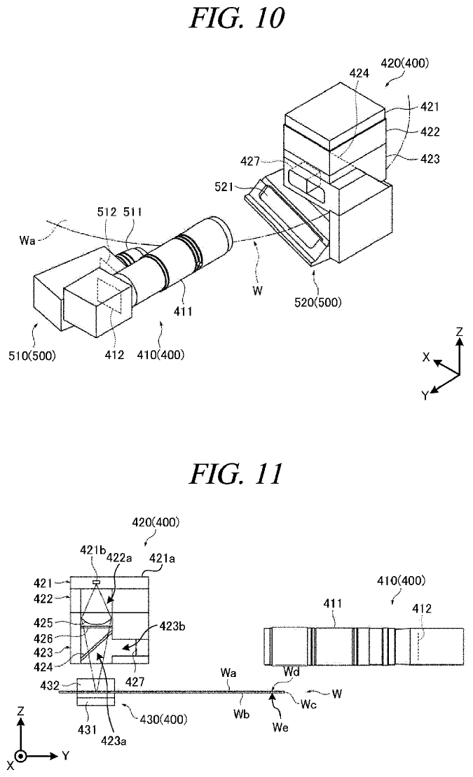

FIG. 9 and FIG. 10 are schematic perspective diagrams illustrating the first imaging sub-unit 400 and the second imaging sub-unit 500. Further, FIG. 11 is a schematic side view illustrating the first imaging sub-unit 400, an illuminating module 420 and a mirror member 430.

As illustrated in FIG. 7 to FIG. 11, the first imaging sub-unit 400 is equipped with a camera 410 (an example of a one surface imaging unit), the illuminating module 420 and the mirror member 430.

The camera 410 has a lens 411 and an imaging element 412. An optical axis of the camera 410 is horizontally extended toward the illuminating module 420.

The illuminating module 420 is disposed above the wafer W held on the holding table 201. The illuminating module 420 includes a light source 421, a light scattering member 422 and a holding member 423.

The light source 421 is equipped with, for example, a housing 421a and a plurality of LED point light sources 421b (only one of them is illustrated in FIG. 11) disposed within the housing 421a. The plurality of LED point light sources 421b are arranged in a row in the diametrical direction of the wafer W.

The light scattering member 422 is connected to the light source 421 to be overlapped with it. The light scattering member 422 is provided with a through hole 422a extending in a direction in which the light source 421 and the light scattering member 422 are overlapped. An inner wall surface of the through hole 422a is mirror-finished. Accordingly, if light from the light source 421 enters the through hole 422a of the light scattering member 422, the incident light is diffuse-reflected on a mirror surface portion within the through hole 422a, so that scattered light is generated.

The holding member 423 is connected to the light scattering member 422 to be overlapped with it. The holding member 423 is provided with a through hole 423a and an intersection hole 423b intersecting with the through hole 423a. The through hole 423a is elongated in a direction in which the light scattering member 422 and the holding member 423 are overlapped. The intersection hole 423b communicates with the through hole 423a.

The holding member 423 holds therein a half mirror 424, a cylindrical lens 425, a light diffusing member 426 and a focus adjusting lens 427. The half mirror 424 is placed at an intersection of the through hole 423a and the intersection hole 423b while being inclined at an angle of, e.g., 45 degrees with respect to a horizontal direction, as shown in FIG. 11. The half mirror 424 has a rectangular shape.

The cylindrical lens 425 is disposed between the light scattering member 422 and the half mirror 424. The cylindrical lens 425 is a cylindrical convex lens projected toward the half mirror 424. An axis of the cylindrical lens 425 is extended in a direction in which the plurality of LED point light sources 421b are arranged. If the scattered light from the light scattering member 422 reaches the cylindrical lens 425, the scattered light is enlarged along a circumferential direction of a cylindrical surface of the cylindrical lens 425.

The light diffusing member 426 is disposed between the cylindrical lens 425 and the half mirror 424. The light diffusing member 426 is, for example, a sheet member having a rectangular shape, and serves to diffuse the light which has penetrated the cylindrical lens 425. Accordingly, diffused light is generated by the light diffusing member 426. By way of example, the light diffusing member 426 may have an isotropic diffusion function whereby it diffuses the incident light in all directions of a surface of the light diffusing member 426. Alternatively, the light diffusing member 426 may have an anisotropic diffusion function whereby it diffuses the incident light toward an axial direction (a direction perpendicular to the circumferential direction of the cylindrical surface of the cylindrical lens 425) of the cylindrical lens 425.

The focus adjusting lens 427 is disposed within the intersection hole 423b. The focus adjusting lens 427 has a function of varying a synthetic focal length with respect to the lens 411.

The mirror member 430 is disposed under the illuminating module 420, and reflects reflection light from an end surface We of the wafer W. The mirror member 430 includes a main body 431 and a reflecting surface 432. The main body 431 is made of, for example, an aluminum block. The reflecting surface 432 faces the end surface Wc and a peripheral region We of the bottom surface Wb of the wafer W held on the holding table 201. The reflecting surface 432 is inclined with respect to a rotation axis of the holding table 201.

The reflecting surface 432 is a gently curved surface recessed away from the end surface Wc of the wafer W held on the holding table 201. Accordingly, if the end surface Wc of the wafer W is reflected on the reflecting surface 432, a mirror shape thereof is enlarged larger than an actual size thereof. A radius of curvature of the reflecting surface 432 is in a range from, e.g., 10 mm to 30 mm. Further, an opening angle (an angle formed by two planes circumscribed about the reflecting surface 432) of the reflecting surface 432 is in a range from, e.g., 100 degrees to 150 degrees.

In the illuminating module 420, light emitted from the light source 421 is scattered by the light scattering member 422, enlarged by the cylindrical lens 425 and diffused by the light diffusing member 426. Then, the light passes through the whole half mirror 424 to be radiated downwards. The diffused light having passed through the half mirror 424 is reflected on the reflecting surface 432 of the mirror member 430 located under the half mirror 424. Reflection light generated as the diffused light is reflected on the reflecting surface 432 is mainly radiated to the end surface Wc of the wafer W and a peripheral region Wd at the top surface Wa side.

Reflection light reflected by the peripheral region Wd of the top surface Wa of the wafer W does not head toward the reflecting surface 432 of the mirror member 430 but is reflected again by the half mirror 424 and passes through the lens 411 of the camera 410 to thereby reach the imaging element 412 of the camera 410, without passing through the focus adjusting lens 427.

Meanwhile, reflection light reflected from the end surface Wc of the wafer W is reflected by the mirror surface 432 of the mirror member 430 and the half mirror 424 in sequence, and then passes through the focus adjusting lens 427 and the lens 411 of the camera 410 to thereby reach the imaging element 412 of the camera 410.

As stated above, both the reflection light from the peripheral region Wd of the top surface Wa of the wafer W and the reflection light from the end surface Wc of the wafer W and the mirror member 430 are inputted to the imaging element 412 of the camera 410. Accordingly, by using the first imaging sub-unit 400, the peripheral region Wd (a region including the top surface peripheral portion) of the top surface Wa of the wafer W and the end surface Wc of the wafer W can be imaged at the same time.

Now, a configuration of the second imaging sub-unit 500 will be explained. The second imaging sub-unit 500 includes a camera 510 (an example of an opposite surface imaging unit) and an illuminating module 520.

The camera 510 is equipped with a lens 511 and an imaging element 512. An optical axis of the camera 510 is extended horizontally toward the illuminating module 520.

The illuminating module 520 is disposed below the illuminating module 420 and located below the wafer W held on the holding table 201. The illuminating module 520 is equipped with a half mirror 521 and a non-illustrated light source. The half mirror 521 is inclined at an angle of, e.g., 45 degrees with respect to the horizontal direction. The half mirror 521 has, for example, a rectangular shape.

The light source is disposed under the half mirror 521. Light emitted from the light source passes through the whole half mirror 521 to be radiated upwards. The light having passed through the half mirror 521 then passes through the lens 511 of the camera 510 and reaches the imaging element 512 of the camera 510. That is, the camera 510 is capable of imaging the bottom surface Wb of the wafer W located in an radiation area of the light source through the half mirror 521.

<Operation of Substrate Processing System>

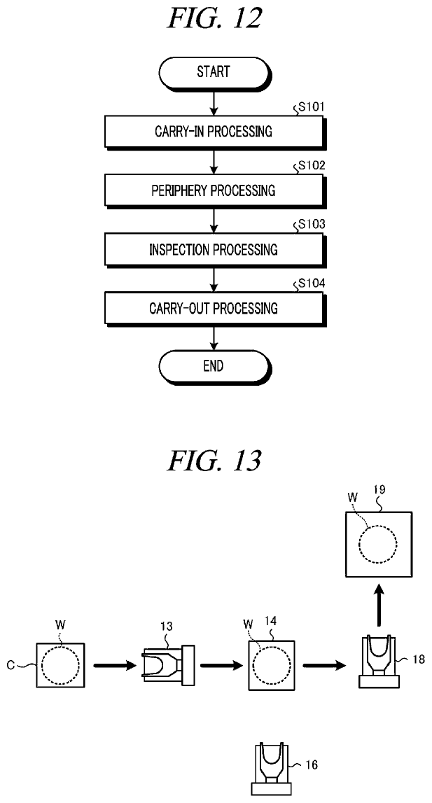

Now, a specific operation of the substrate processing system 1 according to the first exemplary embodiment will be discussed with reference to FIG. 12 to FIG. 15. FIG. 12 is a flowchart illustrating a sequence of processings performed by the substrate processing system 1 according to the first exemplary embodiment. Further, FIG. 13 to FIG. 15 are diagrams illustrating a transfer flow of the wafer W in the substrate processing system 1 according to the first exemplary embodiment. In FIG. 13 to FIG. 15, the flow of the wafer W is indicated by arrows.

As depicted in FIG. 12, in the substrate processing system 1, a carry-in processing is first performed (process S101). The carry-in processing is a processing of carrying the wafers W accommodated in the carrier C into the periphery processing unit 19.

To elaborate, as shown in FIG. 13, the first transfer device 13 takes out the wafers W from the cassette C and places the taken wafers W in the first transit unit 14. At this time, the first transfer device 13 takes out a plurality of wafers W from the cassette C all at once, and places the plurality of taken wafers W in the first transit unit 14 all at once. Then, the third transfer device 18 takes out the wafers W from the first transit unit 14 and carries the taken wafers W into the periphery processing unit 19. At this time, the third transfer device 18 takes out a plurality of (for example, two sheets of) wafers W from the first transit unit 14 and carries the plurality of taken wafers W into a plurality of periphery processing units 19.

Then, in the substrate processing system 1, a periphery processing is performed in the periphery processing unit 19 (process S102). To elaborate, in the periphery processing unit 19, the holder 821 of the substrate holding mechanism 82 holds the wafer W first. As the driver 823 rotates the holder 821, the wafer W held by the holder 821 is rotated. Then, the first moving mechanism 833 and the second moving mechanism 834 locate the upper nozzle 831 and the lower nozzle 832 at preset positions above and below the wafer W, respectively.

Thereafter, the chemical liquid from the chemical liquid source 73 is supplied from the upper nozzle 831 and the lower nozzle 832 onto the top surface peripheral portion and the bottom surface peripheral portion of the wafer W being rotated, respectively. As a result, the film is removed from the bevel portion of the wafer W. Then, the periphery processing unit 19 performs a rinsing processing and a drying processing, and stops the rotation of the wafer W.

Subsequently, in the substrate processing system 1, an inspection processing is performed (process S103). As shown in FIG. 14, the third transfer device 18 takes out the wafer W from the periphery processing unit 19 and carries the taken wafer W into the inspector 15.

In the inspector 15, a notch alignment processing is first performed. The notch alignment processing is a processing of aligning the notch of the wafer W to a preset position. Then, in the inspector 15, an imaging processing is performed. The imaging processing is a processing of imaging the peripheral region Wd of the top surface Wa, the end surface We and the peripheral region We of the bottom surface Wb of the wafer W. The inspector 15 images the top surface peripheral portion and the end surface, and the bottom surface peripheral portion along the entire circumference of the wafer W while rotating the wafer W by using the rotating/holding sub-unit 200. As a result, image data of the top surface peripheral portion and the end surface, and the bottom surface peripheral portion of the wafer W along the entire circumference of the wafer W can be obtained.

Then, in the substrate processing system 1, a carry-out processing is performed (process 104). The carry-out processing is a processing of returning the wafer W after being subjected to the inspection in the inspector 15 back into the cassette C.

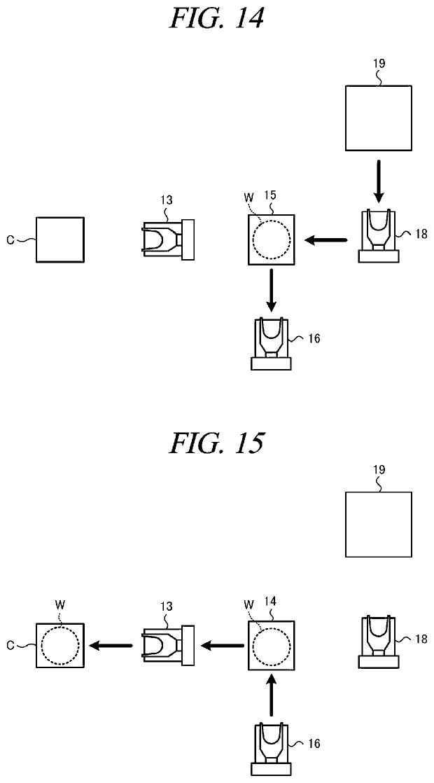

To elaborate, the second transfer device 16 takes out the wafer W from the inspector 15, as shown in FIG. 14, and carries the taken wafer W into the first transit unit 14, as shown in FIG. 15. Then, the first transfer device 13 takes out the wafer W from the first transit unit 14 and carries the taken wafer W back into the cassette C. At this time, the first transfer device 13 may take out a plurality of wafers W placed in the first transit unit 14 all at once, and carry the plurality of taken wafers W back into the cassette C all at once.

In the substrate processing apparatus described in Patent Document 1, the inspector transfer device disposed in the processing station performs the carry-in/carry-out of the substrate into/from the processing unit and the carry-in/carry-out of the substrate into/from the inspector. For the reason, since a processing load on the inspector transfer device is high, there is a concern that a throughput of the processing in the substrate processing apparatus may be limited by the inspector transfer device.

Meanwhile, in the substrate processing system 1 according to the first exemplary embodiment, the second transfer device configured to take out the wafer W from the inspector 15 and carry the taken wafer W into the first transit unit 14 is additionally provided. Accordingly, the processing load on the third transfer device 18 can be reduced. Thus, the limitation in the throughput of the substrate processing system 1 that might be caused by the third transfer device 18 can be suppressed. That is, the throughput of the substrate processing in the substrate processing system 1 can be improved.

### Second Exemplary Embodiment

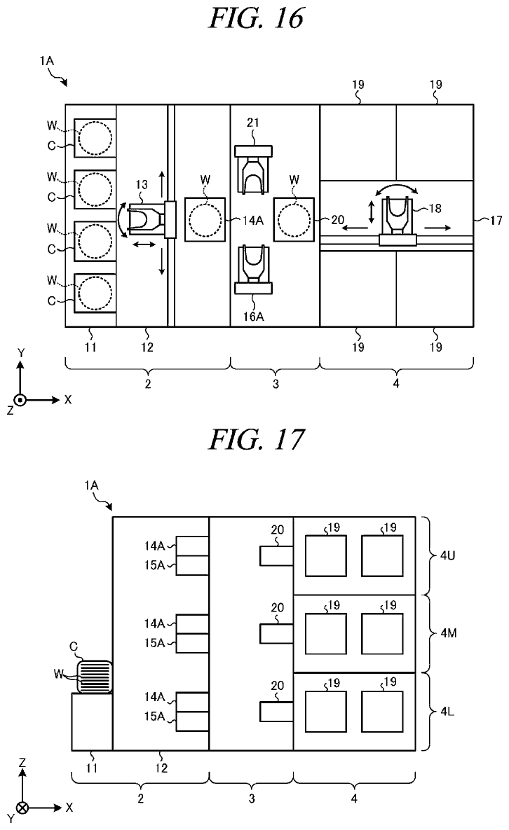

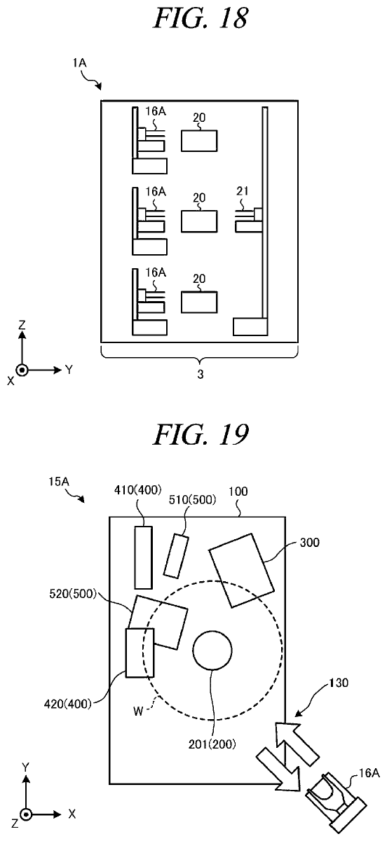

Now, a configuration of a substrate processing system 1A according to a second exemplary embodiment will be explained. In the second exemplary embodiment, the second transfer device 16 is configured not only to take out the wafer W from the inspector 15, but also to carry the wafer W into the inspector 15. FIG. 16 is a top view illustrating a layout of the substrate processing system 1A according to the second exemplary embodiment. FIG. 17 is a side view illustrating the layout of the substrate processing system 1A according to the second exemplary embodiment. In FIG. 17, illustration of various kinds of transfer devices is omitted, and a layout of first transit units 14A, inspectors 15A, second transit units 20 and periphery processing units 19 is mainly illustrated. FIG. 18 is a rear view illustrating a layout of a delivery station of the substrate processing system 1A according to the second exemplary embodiment.

As depicted in FIG. 16 to FIG. 18, the substrate processing system 1A according to the second exemplary embodiment includes a delivery station 3 disposed between a carry-in/out station 2 and a processing station 4.

The delivery station 3 is equipped with the plurality of second transit units 20. Further, the delivery station 3 is provided with a plurality of second transfer devices 16A as an example of inspector transfer devices and a fourth transfer device 21 as an example of a transit unit transfer device.

Each second transit unit 20 is capable of accommodating a plurality of wafers W therein, and the wafers W to be carried into or out of the corresponding periphery processing unit 19 are placed therein. The second transit unit 20 is provided adjacent to a transfer section 17 of the processing station 4. The first transit unit 14A and the second transit unit 20 are arranged in an arrangement direction (X-axis direction) of the carry-in/out station 2, the delivery station 3 and the processing station 4.

The plurality of (here, three) second transit units 20 are stacked in a height direction, and respectively correspond to an upper processing block 4U, a middle processing block 4M and a lower processing block 4L (see FIG. 17). A specific configuration of the second transit unit 20 will be explained later.

The second transfer device 16A and the fourth transfer device 21 are disposed between the first transit unit 14A and the second transit unit 20. To elaborate, the second transfer device 16A and the fourth transfer device 21 are placed at the diagonally rear of the first transit unit 14A and at the diagonally front of the second transit unit 20.

Each of the second transfer device 16A and the fourth transfer device 21 is equipped with a plurality of supports each of which supports a single sheet of wafer W from below it. By way of example, the second transfer device 16A is equipped with two supports, and is capable of performing a carry-in/carry-out of two wafers W with these two supports individually. Meanwhile, the fourth transfer device 21 is equipped with more supports than the second transfer device 16A. For example, the fourth transfer device 21 has five supports.

Each of the second transfer device 16A and the fourth transfer device 21 is movable in a vertical direction and pivotable around a vertical axis. The second transfer device 16A performs a transfer of the wafer W between the second transit unit 20 and the inspector 15A and performs a transfer of the wafer W between the inspector 15A and the first transit unit 14A. Further, the fourth transfer device 21 performs a transfer of the wafer W between the first transit unit 14A and the second transit unit 20.

As depicted in FIG. 18, the plurality of second transfer devices 16A are stacked in the height direction, and respectively correspond to the upper processing block 4U, the middle processing block 4M and the lower processing block 4L. Meanwhile, the only one fourth transfer device 21 is disposed in the delivery station 3, and this single fourth transfer device 21 corresponds to all of the upper processing block 4U, the middle processing block 4M and the lower processing block 4L. That is, the fourth transfer device 21 is capable of transferring the wafer W taken out from the first transit unit 14A into the second transit unit 20 corresponding to one of the upper processing block 4U, the middle processing block 4M and the lower processing block 4L. The fourth transfer device 21 is capable of taking out a plurality of (for example, five sheets of) wafers W from the first transit unit 14A all at once and carrying the plurality of taken wafers W into the second transit unit 20 all at once.

The second transfer device 16A accesses the inspector 15A diagonally. FIG. 19 is a schematic top view of the inspector 15A according to the second exemplary embodiment. As shown in FIG. 19, the inspector 15A according to the second exemplary embodiment is provided with a carry-in/out portion 130 opened toward the second transfer device 16A. To be specific, the carry-in/out portion 130 is diagonally opened toward the arrangement direction of the carry-in/out station 2, the delivery station 3 and the processing station 4. The second transfer device 16A performs a carry-in/carry-out of the wafer W into/from the inspector 15A through the carry-in/out portion 130.

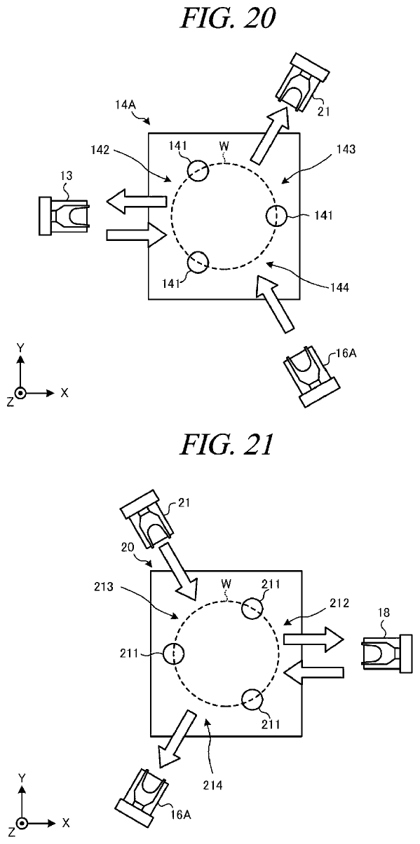

Further, the first transit unit 14A and the second transit unit 20 are configured to be accessible from three different directions. FIG. 20 is a schematic top view illustrating the first transit unit 14A according to the second exemplary embodiment, and FIG. 21 is a schematic top view illustrating the second transit unit 20 according to the second exemplary embodiment.

As shown in FIG. 20, the first transit unit 14A is equipped with, for example, three supporting members 141. Each supporting member 141 is provided with a plurality of grooves formed in a height direction thereof, and each groove supports the bottom surface of the wafer W fitted therein.

The three supporting members 141 are arranged at an angular distance of, e.g., 120 degrees therebetween. The first transfer device 13, the second transfer device 16A and the fourth transfer device 21 access the first transit unit 14A from gaps between every two adjacent supporting members 141 to carry the wafer W into/from the first transit unit 14A.

Specifically, the first transfer device 13 accesses the first transit unit 14A along the arrangement direction (X-axis direction) of the respective stations 2 to 4 through a carry-in/out portion 142 opened toward the first transfer device 13. The fourth transfer device 21 accesses the first transit unit 14A diagonally through a carry-out portion 143 which is opened diagonally with respect to the direction (X-axis direction) to which the carry-in/out portion 142 is opened. Likewise, the second transfer device 16A accesses the first transit unit 14A diagonally through a carry-in portion 144 which is opened diagonally with respect to the direction (X-axis direction) to which the carry-in/out portion 142 is opened.

The second transit unit 20 shown in FIG. 21 has the same configuration as the first transit unit 14A. That is, the second transit unit 20 is equipped with three supporting members 211 arranged at an angular distance of 120 degrees therebetween, and has a carry-in/out portion 212, a carry-in portion 213 and a carry-out portion 214 between the respective supporting members 211.

The third transfer device 18 accesses the second transit unit 20 along the arrangement direction (X-axis direction) of the respective stations 2 to 4 through the carry-in/out portion 212 opened toward the transfer section 17 of the processing station 4. The fourth transfer device 21 accesses the second transit unit 20 diagonally through the carry-in portion 213 which is opened diagonally with respect to the direction (X-axis direction) to which the carry-in/out portion 212 is opened. Likewise, the second transfer device 16A accesses the second transit unit 20 diagonally through the carry-out portion 214 which is opened diagonally with respect to the direction (X-axis direction) to which the carry-in/out portion 212 is opened.

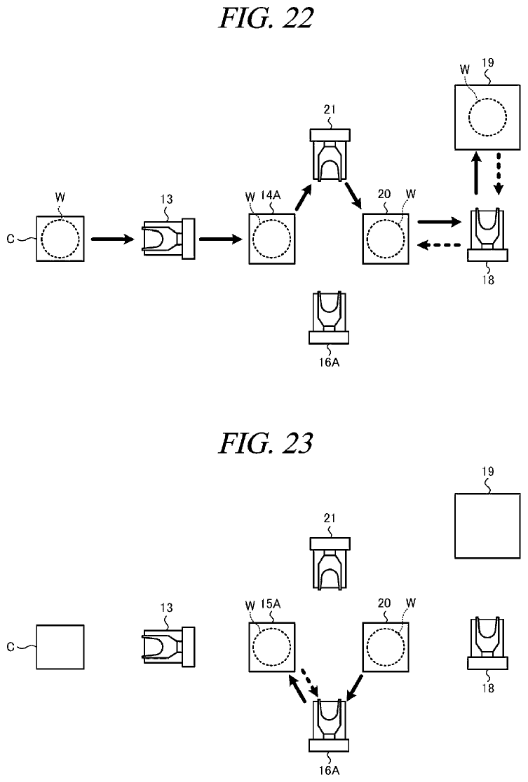

Now, a transfer flow of the wafer W in the substrate processing system 1A according to the second exemplary embodiment will be described with reference to FIG. 22 to FIG. 24. FIG. 22 to FIG. 24 are diagrams illustrating the transfer flow of the wafer W in the substrate processing system 1A according to the second exemplary embodiment. In FIG. 22 to FIG. 24, the flow of the wafer W is indicated by arrows. In FIG. 22 and FIG. 23, when two arrows exist between processing units, a solid-lined arrow indicates an earlier (going) direction, and a dashed-lined arrow indicates a later (returning) direction. Further, a processing sequence of a series of processes of a substrate processing according to the second exemplary embodiment is the same as the processing sequence of the first exemplary embodiment shown in FIG. 12.

As depicted in FIG. 22, the first transfer device 13 first takes out the wafers W from the cassette C and carries the taken wafers W into the first transit unit 14A. At this time, the first transfer device 13 carries a plurality of wafers W into the first transit unit 14A all at once. Then, the fourth transfer device 21 takes out the plurality of wafers W from the first transit unit 14A all at once and carries the taken wafers W into the second transit unit 20 corresponding to one of the upper processing block 4U, the middle processing block 4M and the lower processing block 4L all at once. Further, the fourth transfer device 21 may switch the transfer destination of the wafers W between the upper processing block 4U, the middle processing block 4M and the lower processing block 4L in sequence.

Thereafter, the third transfer device 18 takes out the wafer W from the second transit unit 20 and carries the taken wafer W into the periphery processing unit 19, and the periphery processing unit 19 performs a periphery removing processing on the wafer W. Upon the completion of the periphery removing processing by the periphery processing unit 19, the third transfer device 18 takes out the wafer W from the periphery processing unit 19 and carries the taken wafer W into the second transit unit 20.

Subsequently, as illustrated in FIG. 23, the second transfer device 16A takes out the wafer W from the second transit unit 20 and carries the taken wafer W into the inspector 15A. The inspector 15A performs an inspection processing on the wafer W. Upon the completion of the inspection processing by the inspector 15A, the second transfer device 16A takes out the wafer W from the inspector 15A.

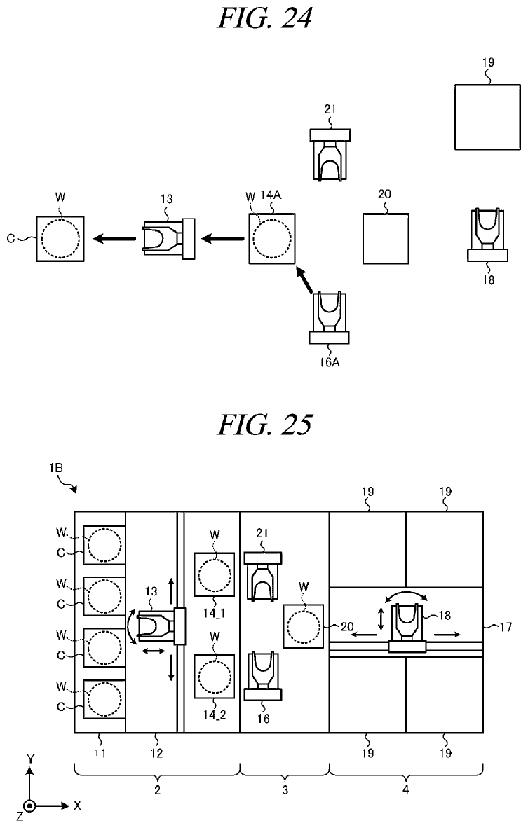

Next, as shown in FIG. 24, the second transfer device 16A carries the wafer W into the first transit unit 14A. Then, the first transfer device 13 takes out a plurality of wafers W accommodated in the first transit unit 14A and puts the taken wafers W in the cassette C.

As stated above, according to the substrate processing system 1A of the second exemplary embodiment, processing loads required for the carry-in of the wafer W into the inspector 15A and the carry-out of the wafer W from the inspector 15A can be reduced from a processing load of the third transfer device 18.

Further, according to the substrate processing system 1A of the second exemplary embodiment, since the fourth transfer device 21 is provided, efficiency of the transfer of the wafer W from the first transit unit 14A to the second transit unit 20 can be improved.

### Third Exemplary Embodiment

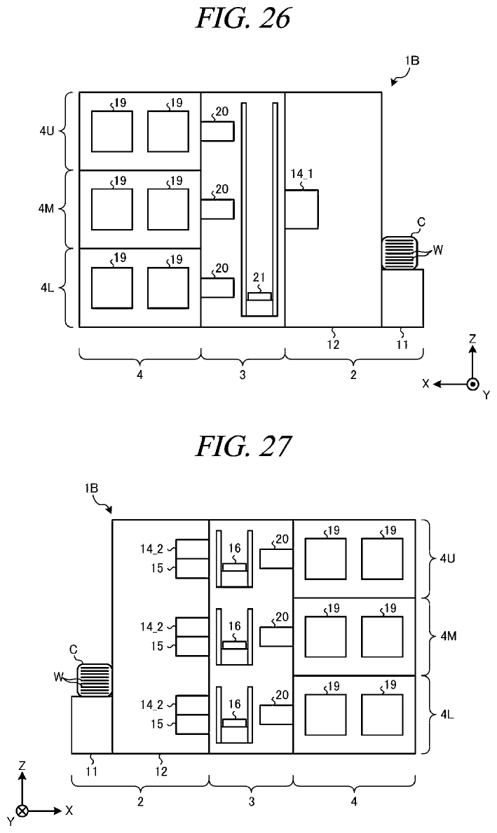

Now, a configuration of a substrate processing system 1B according to a third exemplary embodiment will be explained with reference to FIG. 25 to FIG. 27. FIG. 25 is a top view illustrating a layout of the substrate processing system 1B according to the third exemplary embodiment. FIG. 26 and FIG. 27 are side views illustrating the layout of the substrate processing system 1B according to the third exemplary embodiment.

As depicted in FIG. 25 to FIG. 27, the substrate processing system 1B according to the third exemplary embodiment includes a third transit unit 14_1 and a plurality of fourth transit units 14_2 in a transfer section 12 of a carry-in/out station 2.

The third transit unit 14_1 accommodates therein a wafer W before being processed by a periphery processing unit 19. The third transit unit 14_1 is disposed at a position corresponding to a fourth transfer device 21, specifically, at the front (negative X-axis side) of the fourth transfer device 21. As shown in FIG. 26, the only one third transit unit 14_1 is provided in the transfer section 12 of the carry-in/out station 2.

Each of the plurality of fourth transit units 14_2 accommodates therein the wafer W after being processed by the periphery processing unit 19. The plurality of fourth transit units 14_2 are disposed at positions corresponding to a plurality of second transfer devices 16, respectively, specifically, at the front (negative X-axis side) of the respective second transfer devices 16. That is, as depicted in FIG. 27, each fourth transit unit 14_2 and an inspector 15 corresponding thereto form a single block together, and multiple blocks are arranged at heights respectively corresponding to an upper processing block 4U, a middle processing block 4M and a lower processing block 4L.

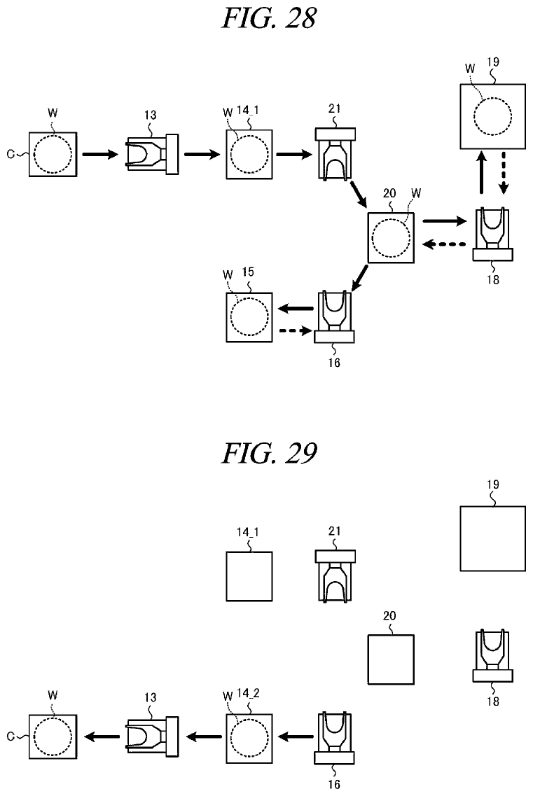

Now, a transfer flow of the wafer W in the substrate processing system 1B according to the third exemplary embodiment will be described with reference to FIG. 28 and FIG. 29. FIG. 28 and FIG. 29 are diagrams illustrating the transfer flow of the wafer W in the substrate processing system 1B according to the third exemplary embodiment.

As depicted in FIG. 28, a first transfer device 13 first takes out wafers W from a cassette C and carries the taken wafers into the third transit unit 14_1. The first transfer device 13 carries a plurality of wafers W into the third transit unit 14_1 all at once. Then, the fourth transfer device 21 takes out the plurality of wafers W from the third transit unit 14_1 all at once, and carries the taken wafers W into a second transit unit 20 corresponding to one of the upper processing block 4U, the middle processing block 4M and the lower processing block 4L.

Then, the third transfer device 18 takes out the wafer W from the second transit unit 20 and carries the taken wafer W into the periphery processing unit 19, and the periphery processing unit 19 performs a periphery removing processing on the wafer W. Upon the completion of the processing by the periphery processing unit 19, the third transfer device 18 takes out the wafer W from the periphery processing unit 19 and transfers the taken wafer W into the second transit unit 20.

Subsequently, the second transfer device 16 takes out the wafer W from the second transit unit 20 and carries the taken wafer W into the inspector 15, and the inspector 15 performs an inspection processing on the wafer W. Upon the completion of the inspection processing by the inspector 15, the second transfer device 16 takes out the wafer W from the inspector 15.

Then, as depicted in FIG. 29, the second transfer device 16 carries the wafer W into the fourth transit unit 14_2. Then, the first transfer device 13 takes out a plurality of wafers W accommodated in the fourth transit unit 14_2 and puts the taken wafers W in the cassette C.

As stated above, according to the substrate processing system 1B of the third exemplary embodiment, as in the second exemplary embodiment, processing loads required for the carry-in of the wafer W into the inspector 15 and the carry-out of the wafer W from the inspector 15 can be reduced from a processing load of the third transfer device 18.

Further, according to the substrate processing system 1B of the third exemplary embodiment, since the third transit unit 14_1 is provided, the access of the second transfer device 16 to the fourth transit unit 14_2 and the access of the fourth transfer device 21 to the third transit unit 14_1 can be performed in parallel. Therefore, according to the substrate processing system 1B of the third exemplary embodiment, a throughput can be further improved.

### First Modification Example

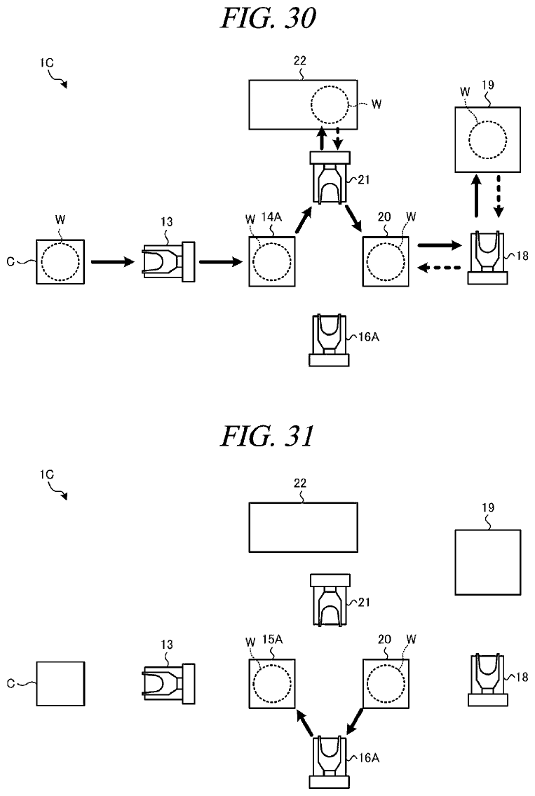

The above exemplary embodiments have been described for the examples where the substrate processing system is equipped with the inspector configured to inspect only a part of the wafer W, that is, the peripheral portion of the wafer W. However, the exemplary embodiments are not limited thereto, and the substrate processing system may be equipped with an inspector configured to inspect an entire surface of the wafer W. This modification example will be described with reference to FIG. 30 and FIG. 31. FIG. 30 and FIG. 31 are diagrams illustrating a transfer flow of the wafer W in a substrate processing system 1C according to a first modification example. Further, FIG. 30 and FIG. 31 illustrate, as an example, a configuration in which an entire surface inspector 22 is provided in the substrate processing system 1A according to the second exemplary embodiment.

As depicted in FIG. 30 and FIG. 31, the substrate processing system 1C according to the first modification example is further equipped with the entire surface inspector 22. The entire surface inspector 22 is disposed across a transfer section 12 of a carry-in/out station 2 and a delivery station 3. Further, the entire surface inspector 22 is disposed at the side (positive Y-axis side) of a fourth transfer device 21.

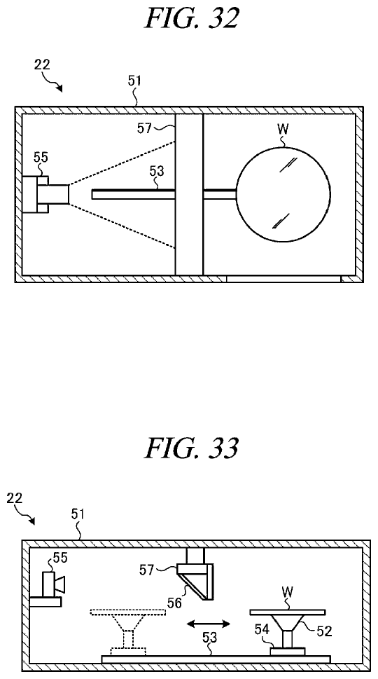

Here, a configuration of the entire surface inspector 22 will be described with reference to FIG. 32 and FIG. 33. FIG. 32 is a cross sectional top view of the entire surface inspector 22 according to the first modification example. FIG. 33 is a cross sectional side view of the entire surface inspector 22 according to the first modification example.

As shown in FIG. 32 and FIG. 33, the entire surface inspector 22 has a casing 51. A holder 52 configured to hold the wafer W is provided within the casing 51. The holder 52 is, for example, a vacuum chuck, and configured to attract and hold a rear surface central portion of the wafer W.

A guide rail 53 extending in the Y-axis direction is provided on a bottom surface of the casing 51. A driver 54 configured to rotate the holder 52 is provided on the guide rail 53. This driver 54 is movable along the guide rail 53.

An imaging unit 55 is provided at an inner sidewall of the casing 51. The imaging unit 55 may be implemented by, for example, a wide-angle CCD camera. A half mirror 56 is provided near an upper center of the casing 51. The half mirror 56 is provided at a position where it faces the imaging unit 55, and a mirror surface thereof is inclined 45 degrees upwards toward the imaging unit 55 with respect to a vertically downward direction.

An illuminating device 57 is provided above the half mirror 56. The half mirror 56 and the illuminating device 57 are fixed to an inner top surface of the casing 51. Light from the illuminating device 57 is radiated downwards through the half mirror 56. Accordingly, the light reflected by an object under the illuminating device 57 is further reflected by the half mirror 56 and then received by the imaging unit 55. That is, the imaging unit 55 is capable of imaging the object located within a radiation region of the illuminating device 57.

The entire surface inspector 22 performs the imaging by the imaging unit 55 while moving the holder 52 along the guide rail 53 by using the driver 54. Accordingly, the entire surface inspector 22 is capable of obtaining images of an entire front surface of the wafer W.

The substrate processing system 1C performs an inspection processing using the entire surface inspector 22 upon the wafer W before being processed by the periphery processing unit 19, for example (see FIG. 30). Then, by using an inspector 15A, the substrate processing system 1C performs an inspection processing upon the wafer W after being processed by the periphery processing unit 19 (see FIG. 31).

First, as shown in FIG. 30, a first transfer device 13 takes out the wafer W from a cassette C and carries the taken wafer W into a first transit unit 14A. Then, a fourth transfer device 21 takes out the wafer W from the first transit unit 14A and carries it into the entire surface inspector 22, and the entire surface inspector 22 performs an inspection processing on the wafer W. Specifically, the entire surface inspector 22 images the entire front surface of the wafer W. Accordingly, a state of the entire front surface of the wafer W before being processed by the periphery processing unit 19, for example, presence or absence of a particle, a film thickness, and so forth can be investigated.

Upon the completion of the inspection processing by the entire surface inspector 22, the fourth transfer device 21 takes out the wafer W from the entire surface inspector 22, and carries the taken wafer W into a second transit unit 20. Operations afterwards are the same as those described in the second exemplary embodiment. That is, as shown in FIG. 31, a second transfer device 16A takes out the wafer W after being processed by the periphery processing unit 19 from the second transit unit 20, and carries the taken wafer W into the inspector 15A. The inspector 15A performs an inspection processing on this wafer W. To be specific, the inspector 15A images a peripheral portion of the wafer W.

As stated above, the substrate processing system 1C may be equipped with the entire surface inspector 22 configured to image the entire surface of the wafer W as well as the inspector 15A configured to image only the peripheral portion of the wafer W.

Further, the entire surface inspector 22 may be plural in number, and these multiple entire surface inspectors 22 may be arranged in multiple levels to correspond to an upper processing block 4U, a middle processing block 4M and a lower processing block 4L. In this configuration, the fourth transfer device 21 may be plural in number, and these multiple fourth transfer devices 21 may also be arranged in multiple levels, the same as the entire surface inspectors 22. With this configuration, a throughput can be improved.

Furthermore, though the present modification example has been described for the case where the substrate processing system 1C has both the inspector 15A and the entire surface inspector 22, the substrate processing system 1C may be equipped with the entire surface inspector 22 only. In this case, the entire surface inspector 22 may be disposed at the side (negative Y-axis side) of the second transfer device 16A, for example, and performs the inspection processing on the wafer W after being processed by the periphery processing unit 19.

### Second Modification Example

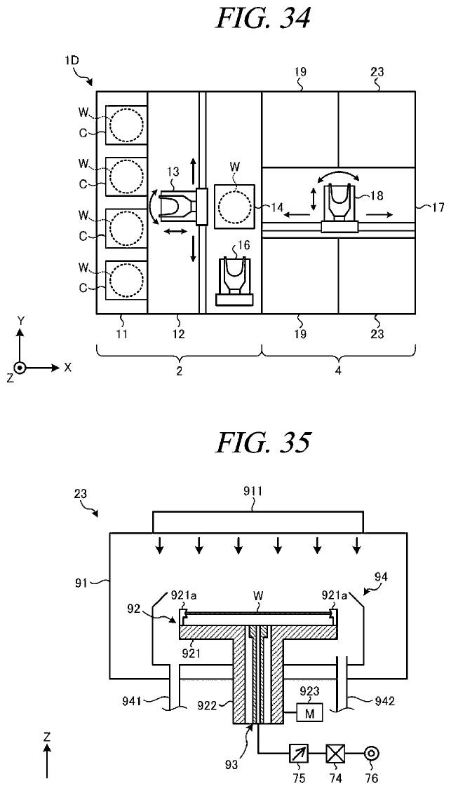

The above exemplary embodiments have been described for the examples where the substrate processing system is equipped with the periphery processing units 19. However, the exemplary embodiments are not limited thereto, and the substrate processing system may be equipped with, in addition to the periphery processing units 19, a bottom surface processing unit (an example of a bottom surface processing device) configured to process an entire bottom surface of a wafer W. This modification example will be explained with reference to FIG. 34 and FIG. 35. FIG. 34 is a top view illustrating a layout of a substrate processing system 1D according to a second modification example. Further, FIG. 35 is a schematic diagram illustrating a bottom surface processing unit according to the second modification example.

As shown in FIG. 34, the substrate processing system 1D according to the second modification example is equipped with a plurality of periphery processing units 19 and a plurality of bottom surface processing units 23 in a processing station 4. To elaborate, some of the periphery processing units 19 and some of the bottom surface processing units 23 are arranged at a positive Y-axis side of a transfer section 17 side by side along the X-axis direction. Further, the others of the periphery processing units 19 and the others of the bottom surface processing units 23 are also arranged at a negative Y-axis side of the transfer section 17 side by side along the X-axis direction.

Each bottom surface processing unit 23 is configured to perform a preset processing on the bottom surface of the wafer W. By way of example, the bottom surface processing unit 23 performs a bottom surface removing processing (an example of a bottom surface processing) of removing a film from the entire bottom surface of the wafer W.

As depicted in FIG. 35, the bottom surface processing unit 23 is equipped with a chamber 91, a substrate holding mechanism 92, a supply 93 and a recovery cup 94. The chamber 91 accommodates therein the substrate holding mechanism 92, the supply 93 and the recovery cup 94. A FFU 911 is provided at a ceiling of the chamber 91 to create a downflow within the chamber 91.

The substrate holding mechanism 92 includes a holder 921 configured to hold the wafer W horizontally; a vertically extending supporting column 922 configured to support the holder 921; and a driver 923 configured to rotate the supporting column 922 around a vertical axis. A plurality of grippers 921a configured to hold a peripheral portion of the wafer W is provided on a top surface of the holder 921, and the wafer W is held horizontally by these grippers 921a while being slightly spaced apart from the top surface of the holder 921.

The supply 93 is inserted through a hollow portion which is formed through the holder 921 and the supporting column 922. A vertically extending path is formed within the supply 93. The path is connected to a chemical liquid source 76 via a valve 74 and a flow rate controller 75. The supply 93 is configured to supply a chemical liquid from the chemical liquid source 76 onto the bottom surface of the wafer W.

The recovery cup 94 is disposed to surround the substrate holding mechanism 92. A drain port 941 is formed at a bottom portion of the recovery cup 94 to drain the chemical liquid supplied from the supply 93 to an outside of the chamber 91. Further, an exhaust port 942 is formed at the bottom portion of the recovery cup 94 to exhaust an atmosphere within the chamber 91.

The bottom surface processing unit 23 is configured as described above, and holds the peripheral portion of the wafer W with the plurality of grippers 921a of the holder 921 and rotates the wafer W by using the driver 923. Then, the bottom surface processing unit 23 discharges the chemical liquid from the supply 93 toward a central portion of the bottom surface of the wafer W being rotated. The chemical liquid supplied onto the central portion of the bottom surface of the wafer W is diffused onto the entire bottom surface of the wafer W as the wafer W is rotated. Accordingly, the film is removed from the entire bottom surface of the wafer W. At this time, a contaminant such as a particle adhering to the bottom surface of the wafer W is also removed along with the film.

Further, after performing the above-described bottom surface removing processing, the bottom surface processing unit 23 may perform a rinsing processing of discharging a rinse liquid such as pure water from the supply 93 to wash away the chemical liquid remaining on the bottom surface of the wafer W. In addition, the bottom surface processing unit 23 may further perform a drying processing of drying the wafer W by rotating the wafer W after the rinsing processing.

Here, the bottom surface processing unit 23 is described to perform the bottom surface removing processing of removing the film from the entire bottom surface of the wafer W as an example of the bottom surface processing. However, the bottom surface processing is not limited to the processing of removing the film. By way of non-limiting example, the bottom surface processing unit 23 may perform a bottom surface cleaning processing of cleaning the entire bottom surface of the wafer W as the bottom surface processing.

In the substrate processing system 1D according to the second modification example, the processing by the bottom surface processing unit 23 is performed on the wafer W after being subjected to the processing by the periphery processing unit 19, for example. Specifically, a third transfer device 18 takes out the wafer W from the periphery processing unit 19 and carries it into the bottom surface processing unit 23. Then, the bottom surface processing unit 23 performs the bottom surface removing processing on the wafer W placed therein. To elaborate, in the bottom surface processing unit 23, the holder 921 of the substrate holding mechanism 92 holds the wafer W first, and the driver 923 rotates the holder 921, thus allowing the wafer W held on the holder 921 to be rotated.

Thereafter, the chemical liquid supplied from the chemical liquid source 76 is discharged from the supply 93 onto a central portion of a bottom surface Wb of the wafer W being rotated. The chemical liquid supplied onto the central portion of the bottom surface Wb of the wafer W is diffused onto the entire bottom surface Wb of the wafer W as the wafer W is rotated. As a result, the film is removed from the entire bottom surface Wb of the wafer W. Then, the bottom surface processing unit 23 performs the rinsing processing and the drying processing, and stops the rotation of the wafer W. Upon the completion of the bottom surface removing processing by the bottom surface processing unit 23, the third transfer device 18 takes out the wafer W from the bottom surface processing unit 23, and carries the taken wafer W into a first transit unit 14.

As described above, the substrate processing system may be equipped with the bottom surface processing unit 23 configured to process the entire bottom surface of the wafer W.

As stated above, the substrate processing apparatus according to the exemplary embodiments (as an example, the substrate processing system 1 (1A to 1D)) includes the processing unit (as an example, the periphery processing unit 19); the transit unit (as an example, the first transit unit 14 (14A); the second transit unit 20; the third transit unit 14_1; the fourth transit unit 14_2); the processing unit transfer device (as an example, the third transfer device 18); the inspector (as an example, the inspector 15 (15A)); and the inspector transfer device (as an example, the second transfer device 16 (16A)). The processing unit processes the peripheral portion of the substrate (as an example, the wafer W). In the transit unit, the delivery of the substrate is performed. The processing unit transfer device performs the carry-in and the carry-out of the substrate between the transit unit and the processing unit. The inspector inspects the processed state of the peripheral portion of the substrate. The inspector transfer device takes out the substrate from the inspector and carries the taken substrate into the transit unit.

Thus, according to the exemplary embodiments, it is possible to suppress the reduction of the throughput that might be caused by the transfer of the substrate in the substrate processing apparatus including the processing unit configured to process the peripheral portion of the substrate and the inspector configured to inspect the peripheral portion of the substrate.

The processing unit transfer device may take out the substrate from the processing unit and carry the taken substrate into the inspector. In this case, the inspector (as an example, the inspector 15) has a carry-in portion (as an example, the carry-in portion 110) and a carry-out portion (as an example, the carry-out portion 120) which are opened to different directions. In this configuration, a carry-in of the substrate by the processing unit transfer device may be performed through the carry-in portion, and a carry-out of the substrate by the inspector transfer device (as an example, the second transfer device 16) may be performed through the carry-out portion.

Accordingly, the processing load required for the transfer of the substrate from the inspector to the transit unit can be reduced from the processing load of the processing unit transfer device.

The substrate processing apparatus according to the exemplary embodiment may be equipped with a plurality of processing units, a plurality of transit units (as an example, the first transit units 14), a plurality of inspectors (as an example, the inspectors 15), a plurality of processing unit transfer devices, and a plurality of inspector transfer devices (as an example, the second transfer devices 16). In this case, the plurality of processing units, the plurality of processing unit transfer devices, and the plurality of inspector transfer devices may be respectively stacked in multiple levels. Further, blocks each of which includes one transit unit and one inspector may be stacked in multiple levels. Further, each of the plurality of inspector transfer devices may carry out a substrate from the inspector of corresponding one of the blocks and carry the taken substrate into the transit unit of this block.

By arranging these components in the multiple levels, the throughput of the substrate processing apparatus in overall can be improved. Further, by providing the inspector transfer devices respectively corresponding to the multiple levels, the reduction of the throughput due to the transfer of the substrate can be suppressed.

The transit units may include a first transit unit (as an example, the first transit unit 14A) in which a substrate to be carried into/from a cassette (as an example, the cassette C) capable of accommodating a multiple number of substrates therein is disposed; and a second transit unit (as an example, the second transit unit 20) in which the substrate to be carried into/from a processing unit is disposed. Further, the substrate processing apparatus according to the exemplary embodiment (as an example, the substrate processing system 1A) may be further equipped with a cassette transfer device (as an example, the first transfer device 13) configured to perform a carry-in/carry-out of the substrate between the cassette and the first transit unit. In this case, the inspector transfer device may take out the substrate from the second transit unit and carry the taken substrate into an inspector (as an example, the inspector 15A), and may take out the substrate from the inspector and carry the taken substrate into the first transit unit.

Accordingly, the processing load required for the carry-in of the substrate into the inspector and the carry-out of the substrate from the inspector can be reduced from the processing load of the processing unit transfer device.

The substrate processing apparatus according to the exemplary embodiment may be further equipped with a transit unit transfer device (as an example, the fourth transfer device 21) configured to take out the substrate from the first transit unit and carry the taken substrate into the second transit unit. By providing the fourth transfer device, efficiency of the transfer of the substrate from the first transit unit to the second transit unit can be improved.

The substrate processing apparatus according to the exemplary embodiment may be equipped with a plurality of processing units, a plurality of first transit units, a plurality of second transit units, a plurality of inspectors, a plurality of processing unit transfer devices and a plurality of inspector transfer devices. In this case, the plurality of processing units, the plurality of second transit units, the plurality of processing unit transfer devices and the plurality of inspector transfer devices may be respectively stacked in multiple levels. Further, blocks including one first transit unit and one inspector may be stacked in multiple levels. Further, the inspector transfer device may correspond to one of the plurality of blocks, and carry out a substrate from the inspector of the corresponding block and carry the taken substrate into the first transit unit of this corresponding block. Further, the transit unit transfer device may correspond to the plurality of first transit units and the plurality of second transit units.

The first transit units may include a third transit unit (as an example, the third transit unit 14_1) in which the substrate before being processed by the processing unit is placed; and a fourth transit unit (as an example, the fourth transit unit 14_2) in which a substrate after being processed by the processing unit is placed. In this case, the transit unit transfer device may take out the substrate before being processed by the processing unit from the third transit unit and carry the taken substrate into the second transit unit. Further, the inspector transfer device may take out the substrate after being processed by the processing unit from the second transit unit and carry the taken substrate into the fourth transit unit.

By providing the third transit unit, the access to the fourth transit unit of the inspector transfer device and the access to the third transit unit of the transit unit transfer device can be carried out in parallel. Accordingly, the throughput can be improved.

The substrate processing apparatus according to the exemplary embodiment may be equipped with a plurality of processing units, a plurality of second transit units, a plurality of fourth transit units, a plurality of inspectors, a plurality of processing unit transfer devices, and a plurality of inspector transfer devices. In this case, since the plurality of processing units, the plurality of second transit units, the plurality of processing unit transfer devices, and the plurality of inspector transfer devices may be respectively stacked in multiple levels. Further, blocks including one fourth transit unit and one inspector may be stacked in multiple levels. Further, the inspector transfer device may correspond to one of the plurality of blocks, and may take out a substrate from the inspector of the corresponding block and carry the taken substrate into the fourth transit unit of this corresponding block. Further, the transit unit transfer device may take out the substrate from the one third transit unit and carry the taken substrate into one of the plurality of second transit units.

The second transit unit is provided with a carry-in/out portion (as an example, the carry-in/out portion 212), a carry-in portion (as an example, the carry-in portion 213), and a carry-out portion (as an example, the carry-out portion 214). The carry-in/out portion is opened toward a transfer section (as an example, the transfer section 17) in which the processing unit transfer device is disposed. The carry-in portion is opened to a first inclined direction with respect to a direction to which the carry-in/out portion is opened, and a carry-in of a substrate by the transit unit transfer device is performed through the carry-in portion. The carry-out portion is opened in a second inclined direction with respect to the direction to which the carry-in/out portion is opened, and a carry-out of the substrate by the inspector transfer device is performed.

By setting the access direction of the transit unit transfer device and the inspector transfer device to the second transit unit to be the inclined direction, the footprint which is the area of the substrate processing apparatus occupied by the substrate processing apparatus on the installation surface can be reduced.

It should be noted that the exemplary embodiment is illustrative in all aspects and is not anyway limiting. The above-described exemplary embodiment may be omitted, replaced and modified in various ways without departing from the scope and the spirit of claims.

According to the exemplary embodiment, it is possible to improve the throughput in the substrate processing apparatus equipped with the processing unit configured to process the peripheral portion of the substrate and the inspector configured to inspect the peripheral portion of the substrate.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a processing unit configured to process a peripheral portion of a substrate;
a transit unit into/from which the substrate is transferred;
a processing unit transfer device configured to perform a carry-in/carry-out of the substrate between the transit unit and the processing unit;
an inspector configured to inspect a processed state of the peripheral portion of the substrate; and
an inspector transfer device configured to take out the substrate from the inspector and carry the taken substrate into the transit unit.

2. The substrate processing apparatus of claim 1,
wherein the processing unit transfer device takes out the substrate from the processing unit and carries the taken substrate into the inspector,
the inspector has a carry-in portion and a carry-out portion which are opened to different directions, and
a carry-in of the substrate by the processing unit transfer device is performed through the carry-in portion, and a carry-out of the substrate by the inspector transfer device is performed through the carry-out portion.

3. The substrate processing apparatus of claim 2,
wherein the processing unit includes multiple processing units, the transit unit includes multiple transit units, the inspector includes multiple inspectors, the processing unit transfer device includes multiple processing unit transfer devices, and the inspector transfer device includes multiple inspector transfer devices,
the multiple processing units, the multiple processing unit transfer devices, and the multiple inspector transfer devices are respectively stacked in multiple levels,
multiple blocks each of which includes one of the multiple transit units and one of the multiple inspectors are stacked in multiple levels, and
each of the multiple inspector transfer devices takes out the substrate from the inspector of corresponding one of the multiple blocks and carries the taken substrate into the transit unit of the corresponding one of the multiple blocks.

4. The substrate processing apparatus of claim 1,
wherein the substrate includes multiple substrates,
wherein the transit unit comprises:
a first transit unit accommodating therein the substrate to be carried into/from a cassette configured to accommodate therein the multiple substrates; and
a second transit unit accommodating therein the substrate to be carried into/from the processing unit,
wherein the substrate processing apparatus further comprises a cassette transfer device configured to perform a carry-in/carry-out of the substrate between the cassette and the first transit unit, and
the inspector transfer device takes out the substrate from the second transit unit and carries the taken substrate into the inspector, and takes out the substrate from the inspector and carries the taken substrate into the first transit unit.

5. The substrate processing apparatus of claim 4, further comprising:
a transit unit transfer device configured to take out the substrate from the first transit unit and carry the taken substrate into the second transit unit.

6. The substrate processing apparatus of claim 5,
wherein the processing unit includes multiple processing units, the first transit unit includes multiple first transit units, the second transit unit includes multiple second transit units, the inspector includes multiple inspectors, the processing unit transfer device includes multiple processing unit transfer devices, and the inspector transfer device includes multiple inspector transfer devices,
the multiple processing units, the multiple second transit units, the multiple processing unit transfer devices, and the multiple inspector transfer devices are respectively stacked in multiple levels,
multiple blocks each of which includes one of the multiple first transit units and one of the multiple inspectors are stacked in multiple levels,
each of the multiple inspector transfer devices corresponds to one of the multiple blocks, and serves to take out the substrate from the inspector of the corresponding one of the multiple blocks and carry the taken substrate into the first transit unit of the corresponding one of the multiple blocks, and
the transit unit transfer device corresponds to the multiple first transit units and the multiple second transit units.

7. The substrate processing apparatus of claim 5,
wherein the first transit unit comprises:
a third transit unit accommodating therein the substrate before being processed by the processing unit; and
a fourth transit unit accommodating therein the substrate after being processed by the processing unit,
wherein the transit unit transfer device takes out the substrate before being processed by the processing unit from the third transit unit and transfers the taken substrate into the second transit unit, and
the inspector transfer device takes out the substrate after being processed by the processing unit from the second transit unit and transfers the taken substrate into the fourth transit unit.

8. The substrate processing apparatus of claim 7,
wherein the processing unit includes multiple processing units, the second transit unit includes multiple second transit units, the fourth transit unit includes multiple fourth transit units, the inspector includes multiple inspectors, the processing unit transfer device includes multiple processing unit transfer devices, and the inspector transfer device includes multiple inspector transfer devices,
the multiple processing units, the multiple second transit units, the multiple processing unit transfer devices, and the multiple inspector transfer devices are respectively stacked in multiple levels,
multiple blocks each of which includes one of the multiple fourth transit units and one of the multiple inspectors are stacked in multiple levels,
each of the multiple inspector transfer devices corresponds to one of the multiple blocks, and serves to take out the substrate from the inspector of the corresponding one of the multiple blocks and carry the taken substrate into the fourth transit unit of the corresponding one of the multiple blocks, and
the transit unit transfer device takes out the substrate from the third transit unit and carry the taken substrate into one of the multiple second transit units.

9. The substrate processing apparatus of claim 5,
wherein the second transit unit comprises:
a carry-in/out portion opened toward a transfer section in which the processing unit transfer device is disposed;
a carry-in portion which is opened to a first inclined direction with respect to a direction to which the carry-in/out portion is opened, and through which a carry-in of the substrate by the transit unit transfer device is performed; and
a carry-out portion which is opened to a second inclined direction with respect to the direction to which the carry-in/out portion is opened, and through which a carry-out of the substrate by the inspector transfer device is performed.

10. The substrate processing apparatus of claim 6,
wherein the second transit unit comprises:
a carry-in/out portion opened toward a transfer section in which the processing unit transfer device is disposed;
a carry-in portion which is opened to a first inclined direction with respect to a direction to which the carry-in/out portion is opened, and through which a carry-in of the substrate by the transit unit transfer device is performed; and
a carry-out portion which is opened to a second inclined direction with respect to the direction to which the carry-in/out portion is opened, and through which a carry-out of the substrate by the inspector transfer device is performed.

11. The substrate processing apparatus of claim 7,
wherein the second transit unit comprises:
a carry-in/out portion opened toward a transfer section in which the processing unit transfer device is disposed;
a carry-in portion which is opened to a first inclined direction with respect to a direction to which the carry-in/out portion is opened, and through which a carry-in of the substrate by the transit unit transfer device is performed; and
a carry-out portion which is opened to a second inclined direction with respect to the direction to which the carry-in/out portion is opened, and through which a carry-out of the substrate by the inspector transfer device is performed.

12. The substrate processing apparatus of claim 8,
wherein the second transit unit comprises:
a carry-in/out portion opened toward a transfer section in which the processing unit transfer device is disposed;
a carry-in portion which is opened to a first inclined direction with respect to a direction to which the carry-in/out portion is opened, and through which a carry-in of the substrate by the transit unit transfer device is performed; and
a carry-out portion which is opened to a second inclined direction with respect to the direction to which the carry-in/out portion is opened, and through which a carry-out of the substrate by the inspector transfer device is performed.

13. A substrate processing method, comprising:
processing a substrate by using a processing unit configured to process a peripheral portion of the substrate;
taking out, by using a processing unit transfer device configured to perform a carry-in/carry-out of the substrate between the processing unit and a transit unit into/from which the substrate is transferred, the substrate from the transit unit to carry the taken substrate into the processing unit;
inspecting, by using an inspector configured to inspect a processed state of the peripheral portion of the substrate, the processed state of the peripheral portion of the substrate processed by the processing unit; and
taking out, by using an inspector transfer device configured to take out the substrate from the inspector and carry the taken substrate into the transit unit, the substrate after being inspected by the inspector from the inspector to carry the taken substrate into the transit unit.
